(19) United States
(12) Patent Application Publication
(10) Pub. No.: US 2012/0037215 A1
(43) Pub. Date: Feb. 16, 2012

(54) PHOTOVOLTAIC MODULE WITH HEATER

(76) Inventors: JASPER T. BALL, Buford, GA (US); BRENDA J. BALL, Buford, GA (US)

(21) Appl. No.: 13/277,148

(22) Filed: Oct. 19, 2011

Related U.S. Application Data
(63) Continuation-in-part of application No. 12/382,669, filed on Mar. 20, 2009.

(51) Int. Cl. H01L 31/048; H01L 31/0203

(52) U.S. Cl. 136/251; 136/259

(57) ABSTRACT

The photovoltaic module with heater is a solar panel with a heated upper surface, thus preventing snow and ice from collecting on the upper surface and diminishing the intensity of sunlight to be converted into electrical power. The photovoltaic module includes a frame formed from aluminum or the like, and at least one photovoltaic cell supported by the frame. A transparent panel is attached to the frame to cover and seal the photovoltaic cell(s) within the frame in a fluid-tight manner. A plurality of heating filaments are embedded within, or disposed on, the transparent panel. The heating filaments are electrically connected to an external power source by a switch for selectively heating the transparent panel and melting any snow or ice that collects thereon.

### CROSS-REFERENCE TO RELATED APPLICATION

This application is a continuation-in-part of U.S. patent application Ser. No. 12/382,669, filed Mar. 20, 2009.

### BACKGROUND OF THE INVENTION

1. Field of the Invention

The present invention relates to solar energy, and particularly to a photovoltaic module with a heater for selectively heating a solar panel to prevent snow and ice from collecting on the solar panel, or for accelerating its removal therefrom, in order to keep the solar panel exposed to sunlight for the generation of electrical power.

2. Description of the Related Art

In the field of photovoltaics, a “photovoltaic module” or “photovoltaic panel” refers to a packaged and interconnected assembly of photovoltaic cells (sometimes also referred to as solar cells). An installation of photovoltaic modules or panels is known as a photovoltaic array. Photovoltaic cells typically require protection from the environment. For reasons of cost and practicality, a number of cells are typically connected together electrically and packaged in a photovoltaic module, which typically includes the photovoltaic cells housed in a frame formed from aluminum or other weather-resistant materials and covered with glass. The glass panel allows transmission of light therethrough, but protects the photovoltaic cells from the elements.

Photovoltaic modules (and panels formed as arrays of such modules) are typically installed on the roofs of houses or office buildings. Although the glass panels of the photovoltaic modules protect the photovoltaic cells from rain, for example, they may easily collect and be covered by snow, sleet, ice and the like. Snow, in particular, severely reduces the intensity of sunlight being received by the photovoltaic cells, thus making solar panel power generation inefficient during winters and in cold climates. Thus, a photovoltaic module with a heater solving the aforementioned problems is desired.

### SUMMARY OF THE INVENTION

The photovoltaic module with a heater is a solar panel with a heated upper surface, thus preventing snow and ice from collecting on the upper surface and diminishing the intensity of sunlight to be converted into electrical power. The photovoltaic module includes a frame formed from aluminum or the like and at least one photovoltaic cell supported by the frame. A transparent panel is secured to the frame to cover and seal the photovoltaic cell(s) in a fluid-tight manner.

A plurality of heating filaments are embedded within or disposed on the transparent panel, the heating filaments being electrically connected to an external power source by a switch for selectively heating the transparent panel and melting any snow or ice that collects thereon.

Alternatively, the conventional heating filaments may be replaced by filaments formed as a thin film on the inner surface of the transparent panel. The thin film is preferably formed from a conductive ink, and may be printed on, or otherwise formed on, the inner surface of the transparent panel by any suitable method of imprinting or thin film formation.

These and other features of the present invention will become readily apparent upon further review of the following specification and drawings.

### BRIEF DESCRIPTION OF THE DRAWINGS

FIG. 1 is an environmental, perspective view of a photovoltaic module with a heater according to the present invention.

FIG. 2 is a plan view of the photovoltaic module of FIG. 1.

FIG. 3 is a side view in section of the photovoltaic module of FIG. 1.

FIG. 4 is a side view in section of an alternative embodiment of a photovoltaic module according to the present invention.

Similar reference characters denote corresponding features consistently throughout the attached drawings.

### DETAILED DESCRIPTION OF THE PREFERRED EMBODIMENTS

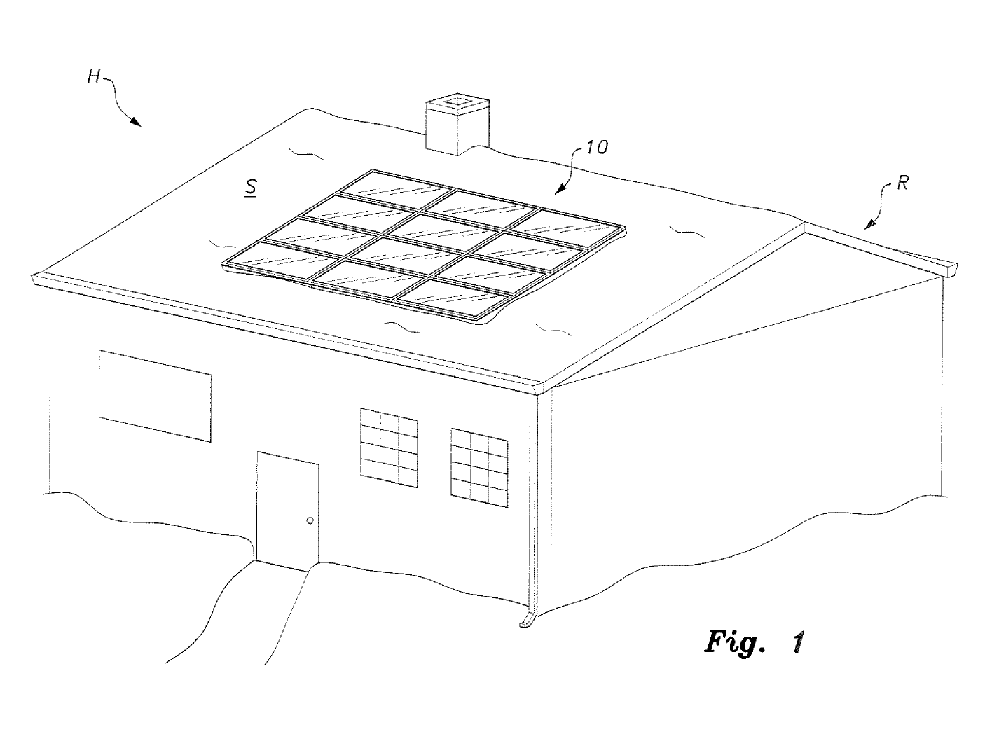

Referring to FIG. 1, the photovoltaic module with heater, designated generally as 10 in the drawings, is shown in an exemplary installation, being mounted on a roof R of a house H. It should be understood that house H and roof R are shown for exemplary purposes only. As will be described in detail below, the photovoltaic module 10 is a solar panel with a heated upper surface, thus preventing snow S and ice from collecting on the upper surface thereof, or permitting accelerated removal of snow S and ice from the solar panel 10, in order to reduce any adverse impact on the generation of electrical power by the solar panel 10.

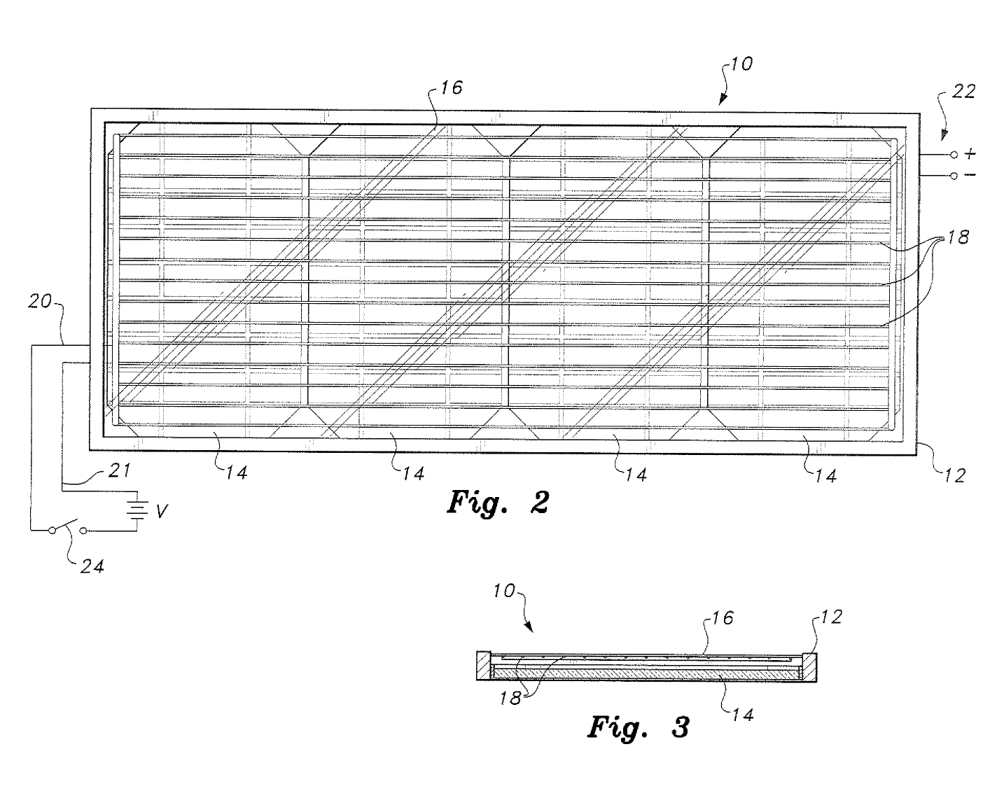

As best shown in FIG. 2, the photovoltaic module 10 includes a frame 12 formed from aluminum or other similar weatherproof or corrosion-resistant material, or from wood, fiberglass, or other rigid backing. At least one photovoltaic cell 14, and generally a plurality of solar cells electrically connected together to cumulate voltage of current generated by the cells, is supported by the frame 12. The panel 10 may have any desired number of photovoltaic cells 14 housed within frame 12, which may have any suitable dimension or configuration. It should be understood that rectangular frame 12 of FIGS. 1 and 2 is shown for exemplary purposes only.

The photovoltaic cell(s) 14 is electrically connected to external leads 22, by which usable electricity, generated by the conversion of solar radiation, may be drawn for storage or powering of external devices. Frame 12 may be secured to roof R by any suitable conventional attachment.

A transparent panel 16 is secured to the frame 12 to cover and seal the photovoltaic cell(s) 14, thus protecting the photovoltaic cell(s) 14 from rain and other environmental hazards. Transparent panel 16 may be formed from glass, plexiglass, or any other suitable, optically transparent material that is also waterproof and capable of forming a fluid-light seal with the frame 12.

A plurality of heating strips or filaments 18 may be embedded within, or disposed on, the transparent panel 16. The heating filaments 18 are electrically connected to an external power source V for selectively heating the transparent panel 16 and melting any snow or ice that collects thereon. Although the power source V is shown schematically by the symbol for a battery, it will be understood that the external power source V may be a connection to the a.c. power mains through an outlet, or directly at a circuit breaker, if desired, Preferably, the plurality of heating filaments 18 are electrically connected together, and are connected via leads 20, 21 to the external power source V, with a switch 24 or other suitable controller being provided for selective control and actuation of the heating filaments 18. Switch 24 may be a thermal or thermostatic switch, a manually operated switch, a timer switch, or any other suitable switch for selectively heating the solar panel 10 to remove snow or ice, or to prevent snow or ice from collecting on the solar panel 10 in inclement weather.

It should be understood that heating filaments 18 may be embedded within glass panel 16 (as shown in FIG. 3) through any suitable process. For example, during manufacture, filaments 18 may be inserted into the heated, liquid glass during the molding of the glass panel 16, or heating filaments 18 may alternatively be laid on an outer surface of glass panel 16 and then laminated over during manufacture. Heating filaments 18 may be embedded therein or, alternatively, adhesively attached to the upper or lower surfaces of glass panel 16 via any suitable process, as is conventionally known in the art of manufacture of heated automobile windshields. Further, it should be understood that any suitable type of heating filaments may be utilized. Such embedded defrosting elements are well known in the art. Examples of such filaments or thermally conductive strips are shown in U.S. Pat. No. 3,813,519 and U.S. Pat. No. 3,995,142, both of which are hereby incorporated by reference in their entirety.

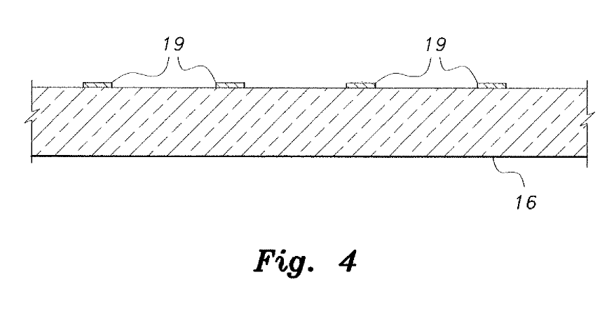

Alternatively, as shown in FIG. 4, conventional heating filaments 18 may be replaced by filaments 19, formed as a thin film on the inner surface of transparent panel 16. The thin film is preferably formed from a conductive ink, and may be printed on, or otherwise formed on, the inner surface of transparent panel 16 by any suitable method of imprinting or thin film formation. It should be further understood that conductive inks are known in the electrical art, and filaments 19 may be formed as a thin film of any suitable type of conductive ink. Examples of conductive inks and thin films made therefrom, as well as methods of forming thin film conductive patterns with conductive inks, are shown in U.S. Pat. Nos. 7,981,327; 7,928,322; 7,806,974; 6,713,399; and 6,315,395, each of which is herein incorporated by reference in its entirety.

It is to be understood that the present invention is not limited to the embodiments described above, but encompasses any and all embodiments within the scope of the following claims.

We claim:

1. A photovoltaic module, comprising:
a frame;
at least one photovoltaic cell supported by the frame;
a transparent panel disposed on the frame, the transparent panel covering the at least one photovoltaic cell; and
a plurality of heating elements thermally connected to the transparent panel, the heating elements being adapted for electrical connection to an external power source for selectively heating the photovoltaic module in order to remove snow and ice therefrom and to prevent the collection of snow and ice on the photovoltaic module, wherein each said heating element comprises a filament formed from conductive ink formed on an inner surface of the transparent panel.

2. The photovoltaic module as recited in claim 1, further comprising a switch electrically connected to said heating elements for selectively switching electrical power to said plurality of heating filaments off and on.

3. The photovoltaic module as recited in claim 1, wherein said transparent panel is formed from glass.

4. The photovoltaic module as recited in claim 1, wherein said frame is substantially rectangular, said transparent panel covering and sealing said at least one photovoltaic cell within said frame.

5. The photovoltaic module as recited in claim 1, wherein each said filament is formed as a thin film of the conductive ink on the inner surface of the transparent panel.

6. A solar panel, comprising:
a frame;
a plurality of solar cells supported by the frame;
a transparent panel attached to the frame, the transparent panel covering the solar cells;
outlet leads adapted for electrically connecting the solar cells to an electrical load for storage and use of electricity generated by the solar cells; and
means for selectively heating the transparent panel to remove snow and ice therefrom and to prevent accumulation of snow and ice on the transparent panel in inclement weather in order to keep the solar cells exposed to sunlight for uninterrupted generation of electrical power, wherein said means for selectively heating the transparent panel comprises at least one filament formed from conductive ink formed on an inner surface of the transparent panel.

7. The solar panel according to claim 6, wherein said frame is made from aluminum.

8. The solar panel according to claim 7, wherein said transparent panel is formed from glass.

9. The solar panel according to claim 8, wherein said means for selectively heating further comprises a switch electrically connected to the at least one filament, the switch being adapted for selectively connecting the at least one filament to a source of electrical power.

10. The photovoltaic module according to claim 9, wherein the at least one filament is formed as a thin film of the conductive ink on the inner surface of the transparent panel.
